(19) United States
(12) Patent Application Publication
(10) Pub. No.: US 2025/0303562 A1
(43) Pub. Date: Oct. 2, 2025

(54) TRANSFER ROBOT TEACHING SYSTEM AND TRANSFER ROBOT TEACHING METHOD

(71) Applicant: DAIHEN Corporation, Osaka (JP)

(72) Inventor: Yoshihiro SUTO, Osaka (JP)

(21) Appl. No.: 19/090,012

(22) Filed: Mar. 25, 2025

(30) Foreign Application Priority Data
Mar. 29, 2024 (JP) 2024-056171

(51) Int. Cl. B25J 9/16; B25J 13/08; B25J 19/02

(52) U.S. Cl. CPC B25J 9/163; B25J 13/08; B25J 19/021

(57) ABSTRACT

A teaching system is provided for a transfer robot including a vertical arm assembly, a rotation member rotatable about a horizontal axis extending in x direction, a horizontal arm assembly supported by the rotation member, a hand supported by the rotation member and provided with an object detection sensor, and a control device configured to detect a target with the detection sensor and teach a position of the hand based on the detection result. The target includes a transparent cylindrical portion having a vertical center line. The detection sensor includes a light emitter and a light receiver. The control device is configured to move the hand along y direction from a predetermined first state to a predetermined second state, and adjust the position of the hand in y direction based on the travel distance of the hand between the first state and the second state.

### FIELD

The present disclosure relates to a transfer robot teaching system and a transfer robot teaching method.

### BACKGROUND

In the manufacture of semiconductor substrates and liquid crystal substrates, substrates are stored into a multi-level storage container called a cassette and transferred to processing and inspection devices where they are processed and inspected. At the processing and inspection devices, the substrates are loaded into and unloaded from the cassette using industrial robots called transfer robots. To enable a transfer robot to perform the loading and unloading tasks, a human operator needs to perform teaching work in advance to teach the necessary movements and actions.

The teaching work is extremely time-consuming. The slots in cassettes for storing substrates are very narrow and have little clearance. In addition, the inside of some cassettes may not be visible except from their open side, and a transfer robot is typically located in front of the open side. Thus, the inside of the cassette is not readily visible. For the teaching work, an operator needs to manually operate the transfer robot to place substrates into and out of such narrow slots, relying on their own eye and intuition.

JP-A-2015-153809 discloses a configuration in which an object detection sensor is attached to a hand of a robotic arm and detects a protrusion on a jig. Teaching work is performed based on detection results. This configuration eliminates the need for manual operations by an operator for teaching and thus reduces the time required for the teaching work. However, depending on the configurations of transfer robots, the technique disclosed in the document may not enable efficient teaching work.

### SUMMARY

The present disclosure has been made in light of the circumstances described above, and its main objective is to provide a teaching system for a transfer robot for efficient teaching work.

To solve the above issues, the present disclosure provides the following technical solutions.

According to a first aspect of the present disclosure, there is provided a teaching system for a transfer robot, the robot provided with: a vertical arm assembly of a vertical articulated type configured to move in an in-plane direction perpendicular to a horizontal first direction; a first rotation member supported by the vertical arm assembly to be rotatable around a first rotation axis extending in the first direction; a horizontal arm assembly of a horizontal articulated type supported by the first rotation member; a hand supported by the horizontal arm assembly and provided with an object detection sensor; and a control device that detects a detection target with the object detection sensor while moving the hand and teaches a position of the hand using a detection result. The detection target includes a cylindrical portion made of a light-transmitting material and having a center line extending in a vertical direction perpendicular to the first direction. The object detection sensor includes a light emitter and a light receiver for receiving light from the light emitter. The control device is configured to: rotate the hand by a predetermined angle around a vertical axis located at a midpoint of an optical axis of the object detection sensor and extending in the vertical direction; move the hand in a second direction perpendicular to the first direction and the vertical direction from a first state in which light form the light emitter passes through the cylindrical portion to a second state in which the light receiver receives a maximum amount of light; and adjust a position of the hand in the second direction based on a travel distance of the hand from the first state to the second state.

In a preferred embodiment, the detection target includes a block portion that is made of a light-transmitting material, and the block portion includes a first surface facing toward a first side in the second direction and a second surface facing toward a second side in the second direction and parallel to the first surface.

In a preferred embodiment, the cylindrical portion is located on an upper side in the vertical direction with respect to the block portion.

In a preferred embodiment, the detection target is made of colorless transparent glass or colored transparent glass.

According to a second aspect of the present disclosure, there is provided a teaching method for a transfer robot, the robot provided with: a vertical arm assembly of a vertical articulated type configured to move in an in-plane direction perpendicular to a first direction that is horizontal; a first rotation member supported by the vertical arm assembly to be rotatable around a first rotation axis that extends in the first direction; a horizontal arm assembly of a horizontal articulated type supported by the first rotation member; and a hand supported by the horizontal arm assembly and provided with an object detection sensor, wherein the teaching method is configured to detect a detection target with the object detection sensor while moving the hand and teach a position of the hand using a detection result. The detection target includes a cylindrical portion made of a light-transmitting material and having a center line extending in a vertical direction perpendicular to the first direction. The object detection sensor includes a light emitter and a light receiver for receiving light from the light emitter. The method comprises: rotating the hand by a predetermined angle around a vertical axis located at a midpoint of an optical axis of the object detection sensor and extending in the vertical direction to bring the hand into a first state in which light form the light emitter passes through the cylindrical portion; recording a position of the hand in the first state as a first position; moving the hand in a second direction to bring the hand into a second state in which the light receiver receives a maximum amount of light and recording a position of the hand that is in the second state as a second position; and adjusting a position of the hand in the second direction based on a travel distance of the hand from the first position to the second position.

The transfer robot teaching system according to the present invention is applicable to a transfer robot provided with a vertical arm assembly, a first rotation member, and a horizontal arm assembly, and enables efficient adjustment of the hand of the transfer robot in the second direction that is perpendicular to the horizontal first direction and the vertical direction.

Other features and advantages of the present disclosure will be more apparent from the detailed description given below with reference to the attached drawings.

### DRAWINGS

FIG. 1 is a schematic front view of an example of a transfer robot included in a transfer robot teaching system according to the present disclosure.

FIG. 2 is a perspective view of the transfer robot shown in FIG. 1.

FIG. 3 is a perspective view of an example of an arrangement of a detection target.

FIG. 4 is a perspective view showing the relative positions of a detection target and a hand.

FIG. 5 is an enlarged perspective view of the detection target.

FIG. 6 is a block diagram of the control of the transfer robot.

FIG. 7 is a flowchart of a teaching process.

FIG. 8 is a view illustrating an example of an x-direction adjustment process.

FIG. 9 is a view illustrating an example of a z-direction adjustment process.

FIG. 10 is a view illustrating an example of an x- and z-axis rotation direction adjustment process.

FIG. 11 is a view illustrating an example of an x- and z-axis rotation direction adjustment process.

FIG. 12 is a flowchart of an example of an x- and z-axis rotation direction adjustment process.

FIG. 13 is a view for illustrating a method for determining the angles of rotation around the x- and z-axes at which the amount of light received by a light receiver is at its maximum.

FIG. 14 is a view illustrating an example of a y-direction adjustment process.

FIG. 15 is a flowchart of an example of a y-direction adjustment process.

### EMBODIMENTS

The following describes preferred embodiments of the present disclosure with reference to the drawings.

In the present disclosure, the terms such as “first”, “second”, and so on are used only as labels and do not imply an order of the items referred to by the terms.

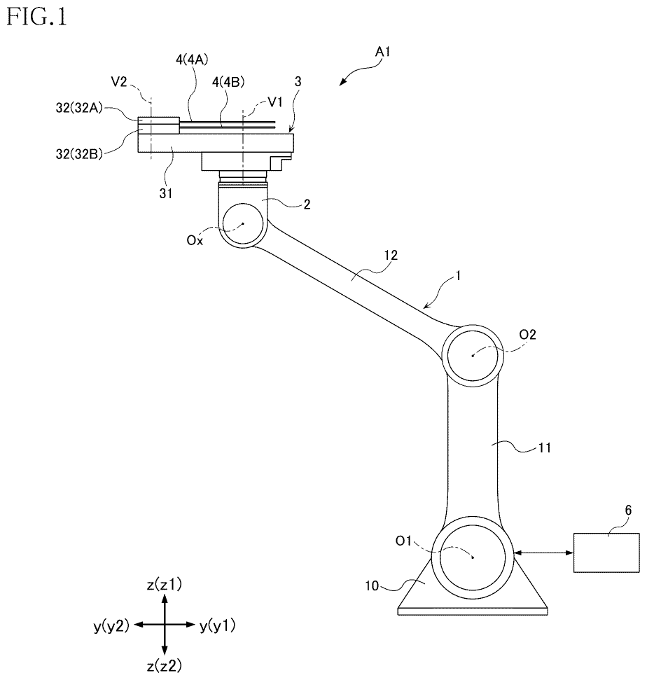

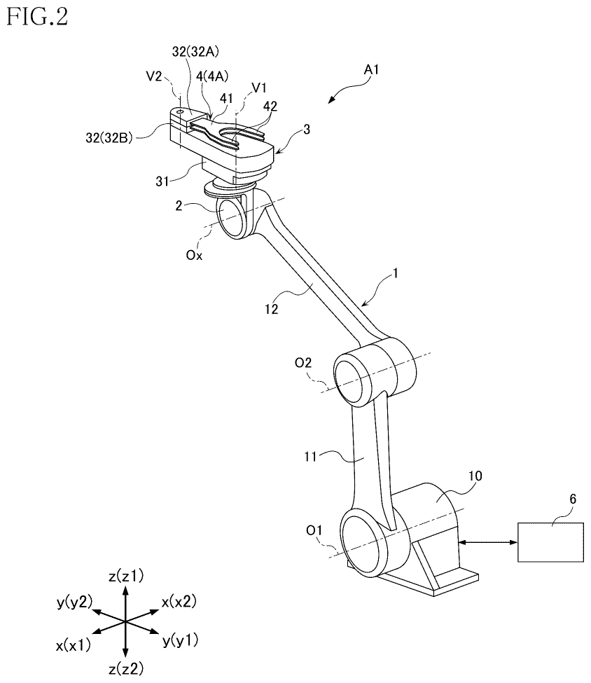

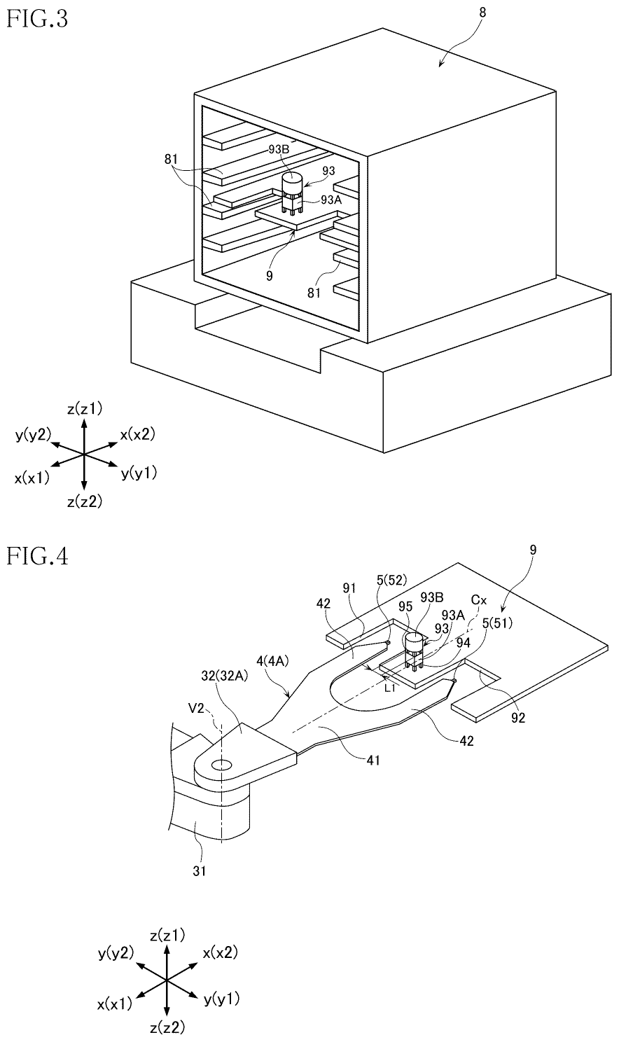

FIG. 1 is a schematic front view of an example of a transfer robot included in a transfer robot teaching system according to the present disclosure. The transfer robot A1 shown in FIG. 1 performs multiple tasks. For example, the transfer robot A1 takes out substrates from a multi-level storage cassette 8 (see FIG. 3) located at a load port, transfers the substrates to a load-lock chamber located opposite the cassette 8, removes the substrates having been processed in a processing chamber from the load-lock chamber, and places the substrates back into the cassette 8.

The transfer robot A1 includes a vertical arm assembly 1, a first rotation member 2, a horizontal arm assembly 3, a hand 4, a control device 6, a drive mechanism 71, and an input unit 72.

In the illustrated example of the present embodiment, the x direction corresponds to the “first direction” of the present disclosure, and the y direction corresponds to the “second direction” of the present disclosure. The x and y directions are perpendicular to each other, and both are parallel to the horizontal plane. The z direction is perpendicular to the x and y directions and corresponds to the vertical direction when the transfer robot A1 is installed in a transfer chamber (not shown), for example. The z direction also corresponds to the “vertical direction” of the present disclosure. In the following description, the upper side in the z direction may be referred to as the “z1 side in the z direction”, and the lower side as the “z2 side in the z direction” as necessary. The z1 side in the z direction corresponds to the “upper side in the vertical direction” of the present disclosure, and the z2 side in the z direction corresponds to the “lower side in the vertical direction”. In addition, one side in the x direction may be referred to as the “x1 side in the x direction”, and the other side as the “x2 side in the x direction” as necessary. The x1 side in the x direction corresponds to the “first side in the first direction” of the present disclosure, and the x2 side in the x direction corresponds to the “second side in the first direction”. One side in the y direction may be referred to as the “y1 side in the y direction”, and the other side as the “y2 side in the y direction” as necessary. The y1 side in the y direction corresponds to the “first side in the second direction” of the present disclosure, and the y2 side in the y direction corresponds to the “second side in the second direction”. Further, “A surface A faces in a direction B (or toward a first or second side in the direction B) is not limited, unless otherwise specifically noted, to the situation where the surface A forms an angle of 90° with the direction B but includes the situation where the surface A is inclined with respect to the direction B.

The vertical arm assembly 1 is of a vertical articulated type that moves in the directions within a plane perpendicular to the horizontal x direction and is composed of a plurality of arms that are joined to be rotatable, for example. In the illustrated example, the vertical arm assembly 1 includes a first vertical arm 11 and a second vertical arm 12. The first vertical arm 11 extends within a plane defined by the y and z directions and is supported by a fixed base 10. Specifically, the first vertical arm 11 has a proximal end supported by the fixed base 10 to be rotatable around a first horizontal axis O1 that extends in the x direction. The second vertical arm 12 extends within a plane defined by the y and z directions and is supported by the first vertical arm 11. Specifically, the second vertical arm 12 has a proximal end supported by the distal end of the first vertical arm 11 to be rotatable around a second horizontal axis O2 that extends in the x direction. The configuration of the vertical arm assembly 1 is not limited to the illustrated example.

The first rotation member 2 is supported by the second vertical arm 12 (the vertical arm assembly 1). Specifically, the first rotation member 2 is supported by the distal end of the second vertical arm 12 to be rotatable around a first rotation axis Ox that extends in the x direction.

Although not shown or described in detail, the first vertical arm 11 and the second vertical arm 12 are driven by a motor through power transmission means (a drive mechanism), such as belts and reduction gears, to rotate around the first horizontal axis O1 and the second horizontal axis O2. By driving the motor, the horizontal arm assembly 3, which is supported by the vertical arm assembly 1 via the first rotation member 2, is moved to the front of the cassette or the load-lock chamber. The first rotation member 2 is driven to rotate around the first rotation axis Ox by a drive mechanism not shown in the figures. Thus, the horizontal arm assembly 3 (a first horizontal arm 31 and a second horizontal arm 32 described later) that is supported by the first rotation member 2 is kept in the horizontal position.

The horizontal arm assembly 3, which is supported by the first rotation member 2, is of a horizontal articulated type and moves in the directions within a horizontal plane perpendicular to the z direction (the vertical direction). The horizontal arm assembly 3 may be composed of a plurality of arms that are joined to be rotatable. In the illustrated example, the horizontal arm assembly 3 includes a first horizontal arm 31 and a second horizontal arm 32. The first horizontal arm 31 has a proximal end supported by the first rotation member 2 to be rotatable around a first vertical axis V1 that extends in the z direction. The second horizontal arm 32 has a proximal end supported by the distal end of the first horizontal arm 31 to be rotatable around a second vertical axis V2 that extends in the z direction. In the present embodiment, the second horizontal arm 32 includes two second horizontal arms 32A and 32B that are stacked one on top of the other. The configuration of the horizontal arm assembly 3 is not limited to the illustrated example.

Although not shown or described in detail, the first horizontal arm 31 and the second horizontal arm 32 may be driven by a motor through power transmission means (a drive mechanism), such as belts and reduction gears, to rotate around the first vertical axis V1 and the second vertical axis V2. By controlling the motor, the hand 4 (hands 4A and 4B described later), which is supported by the second horizontal arm 32 (the second horizontal arms 32A and 32B), is moved linearly in the horizontal x direction.

The hand 4 is supported by the second horizontal arm 32 (the horizontal arm assembly 3). Specifically, the hand 4 is attached to the second horizontal arm 32. In the present embodiment, the hand 4 includes the two hands 4A and 4B that are stacked one on top of the other. The hands 4A and 4B are respectively attached to the second horizontal arms 32A and 32B.

The hand 4 (the hands 4A and 4B) is a substantially U-Shaped plate having a base portion 41 connected to the second horizontal arm 32 (the second horizontal arms 32A and 32B) and two holding portions 42 extending from the base portion 41. In the state shown in FIG. 4, the two holding portions 42 of the hand 4 are spaced apart in the y direction. The hand 4 is used to support a thin substrate (not shown). The configuration of the hand 4 is not limited to the illustrated example.

The transfer robot A1 keeps the hand 4 horizontal to support a substrate. With this state, the transfer robot A1 moves the hand 4 up and down or rotates the hand 4 within the xy plane to place a substrate into a slot 81 of the cassette 8 (loading of a substrate into the cassette 8) or to receive a substrate stored in a slot 81 and take the substrate out of the cassette 8 (unloading of a substrate from the cassette 8).

The object detection sensor 5 is attached to the end of the hand 4. Details of the object detection sensor 5 will be described later.

The cassette 8 has the shape of a rectangular parallelepiped box. The cassette 8 is open on at least the side facing the transfer robot A1 to allow for the loading and unloading of substrates. The cassette 8 has a plurality of ledges on the opposite inner surfaces, creating a plurality of slots 81 for storing a plurality of substrates at multiple levels. A substrate is held in a slot 81 by being supported on the upper surfaces of a pair of ledges provided at the same height. The length of the gap between the two opposing ledges forming each slot 81 in the cassette 8 is longer than the length of the hand 4 in the lateral direction (the width of the hand 4). This allows the hand 4 to move up and down within the cassette 8 without interfering with the ledges of the slots 81.

In one example, the object detection sensor 5 is a fiber sensor, which is a type of an optical sensor. The fiber sensor includes a light emitter 51 and a light receiver 52 and detects the presence of an object between them based on whether or not light from the light emitter 51 is received by the light receiver 52. For the fiber sensor, the light emitter 51 emits red light (visible light), for example. The object detection sensor 5 is not limited to a fiber sensor and can be any suitable sensor that detects an object based on whether or not light from the light emitter 51 is received by the light receiver 52. In addition, the light of the light emitter 51 is not limited to visible light and may be infrared light, for example. The following description assumes that the object detection sensor 5 is a fiber sensor. As shown in FIG. 4, the light emitter 51 of the object detection sensor 5 is attached to the tip of one holding portion 42 of the hand 4, and the light receiver 52 is attached to the tip of the other holding portion 42.

The object detection sensor 5 is provided for detecting each slot 81 of the cassette 8 that stores a substrate. Specifically, the transfer robot A1 moves the hand 4 in the vertical direction (in the z direction shown in FIG. 4) while the light emitter 51 emits light toward the light receiver 52. The hand 4 is moved such that the optical axis of the object detection sensor 5 will be blocked by an edge of a substrate placed in a slot 81 without any contact between the hand 4 and the substrate. In the absence of a substrate in the slot 81, the light from the light emitter 51 is received by the light receiver 52. In the presence of a substrate in the slot 81, the light from the light emitter is blocked by the substrate and thus is not received by the light receiver 52. Thus, each slot 81 that stores a substrate is determined based on the detection results of the object detection sensor 5. When no object is present between the light emitter 51 and the light receiver 52, and thus the optical axis of the object detection sensor 5 is not blocked, the detection state is ON, in which the light from the light emitter 51 is received by the light receiver 52. When the optical axis of the object detection sensor 5 is not blocked, the amount of light (intensity of light) received by the light receiver 52 is at its maximum. In contrast, when an object (e.g., an edge of a substrate) is present between the light emitter 51 and the light receiver 52, the detection state is OFF, in which the light from the light emitter 51 is not received by the light receiver 52. The definitions of ON and OFF of the detection state also apply to the following description.

The control device 6 controls the movements of the vertical arm assembly 1, the first rotation member 2, and the horizontal arm assembly 3 and teaches the positions of the hand 4. As shown in FIG. 6, the control device 6 includes a control unit 61 and a storage unit 62. The control unit 61 controls the drive mechanism 71 based on teaching information stored in the storage unit 62. The drive mechanism 71 drives the vertical arm assembly 1, the first rotation member 2, and the horizontal arm assembly 3 to execute predetermined movements. The control unit 61 also controls the drive mechanism 71 based on information entered into the input unit 72. The input unit 72 is a device that allows an operator to perform teaching work or manual operations (e.g., a teach pendant). The control unit 61 assists teaching work based on a teaching process described below to automatically perform the teaching work. The teaching process will be described later. The storage unit 62 stores teaching information that describes the movement trajectory of the hand 4. The teaching information is obtained in advance through the teaching process and stored in the storage unit 62.

According to the present embodiment, teaching work is automatically performed using the object detection sensor 5 provided on the hand 4 and a jig 9 placed on the upper surfaces of a pair of ledges forming a slot 81 in the cassette 8 as shown in FIGS. 3 and 4. Through the automatic teaching work, the positions of the hand 4 are used for teaching to adjust the hand 4 to a predetermined position.

The jig 9 may be a dummy substrate that is similar to an actual thin substrate to be stored into the cassette 8. The material of the jig 9 is not specifically limited. The jig 9 may be made of the same material as an actual substrate or a different material. The jig 9 is placed in a slot 81 of the cassette 8 (see FIG. 3). In the present embodiment, the jig 9 has a rectangular shape that closely matches the inner surfaces of the cassette 8 so that the position of the jig 9 (the position in the xy plane) in the cassette 8 does not vary. Specifically, the jig 9 has a width (in the y direction in FIG. 3) that is slightly narrower than the inside width (in the y direction) of the cassette 8. This allows the jig 9 to fit into the cassette 8, while preventing positional deviations in the width direction (the y direction) within the cassette 8. In addition, the jig 9 is placed at the farthest end in a slot 81 to prevent positional deviations in the depth direction of the cassette 8 (the x direction). This ensures that a detection target 93, which will be described later, is placed at the specific position on the xy plane. Note that the shape of the jig 9 is not limited to the example described above and may be any suitable shape allowing detection of the position of the detection target 93 on the xy plane.

The jig 9 has two notches 91 and 92 in the edge on the open side of the cassette 8 (the x1 side in the x direction in FIG. 3) when the jig 9 is placed in a slot 81 in the cassette 8. The notches 91 and 92 of the jig 9 are provided to avoid contact with the holding portions 42 of the hand 4. Thus, the shape of the notches 91 and 92 are not specifically limited, and other shapes suitable for this purpose may be used. The detection target 93 is disposed on the upper surface of the jig 9 at a location between the notches 91 and 92.

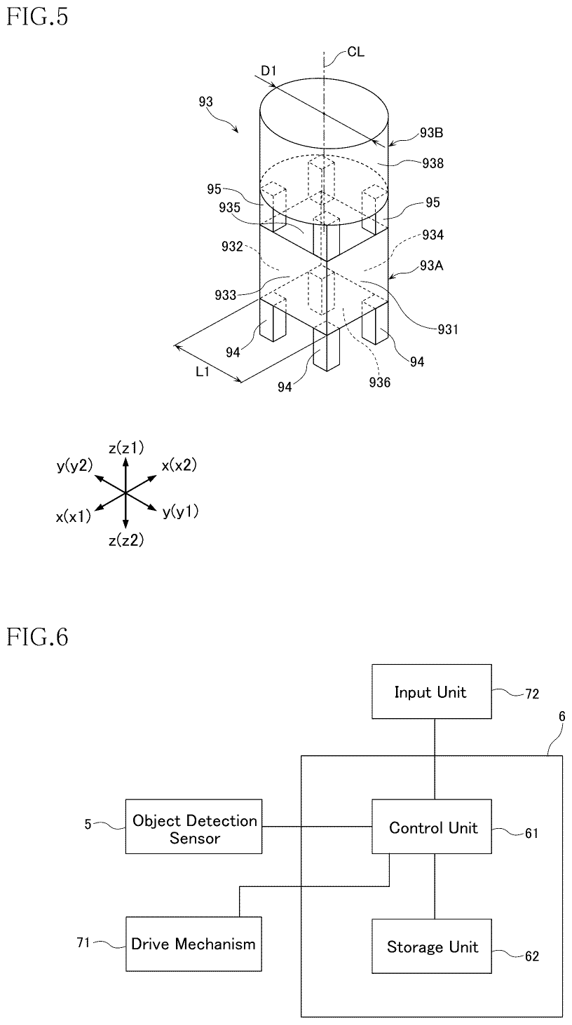

As shown in FIGS. 4 and 5, in the present embodiment, the detection target 93 includes a block portion 93A and a cylindrical portion 93B. The block portion 93A may have the shape of a rectangular parallelepiped or a cube, for example. In the illustrated example, the block portion 93A has the shape of a cube. The block portion 93A has six surfaces. Specifically, as shown in FIG. 5, the block portion 93A has a first surface 931, a second surface 932, a third surface 933, a fourth surface 934, a fifth surface 935, and a sixth surface 936. The first surface 931 and the second surface 932 face away from each other in the y direction and are parallel to each other. The first surface 931 faces toward the y1 side in the y direction, and the second surface 932 faces toward the y2 side in the y direction. The third surface 933 and the fourth surface 934 face away from each other in the x direction. The third surface 933 faces toward the x1 side in the x direction, and the fourth surface 934 faces toward the x2 side in the x direction. The fifth surface 935 and the sixth surface 936 face away from each other in the z direction. The fifth surface 935 is the upper surface facing toward the z1 side in the z direction. The sixth surface is the lower surface facing toward the z2 side in the z direction. The lower surface (the sixth surface 936) of the block portion 93A is supported at its four corners by four legs 94. By these legs 94, the block portion 93A (the detection target 93) is supported on and secured to the jig 9. The length L1 of a side of the block portion 93A may be, but not limited to, about 30 mm, for example. Note that the shape of the block portion 93A is not limited to a cube, and any other suitable shape having a distinct first surface 931 and a distinct second surface 932 is appropriate.

The cylindrical portion 93B is located on the z1 side in the z direction (the upper side in the vertical direction) with respect to the block portion 93A. The cylindrical portion 93B has the shape of a cylinder with its center line CL extending in the z direction. The cylindrical portion 93B is supported on the block portion 93A with a plurality of legs 95. The legs 95 are provided at the four corners of the upper surface (the fifth surface 935) of the block portion 93A. By these legs 95, the cylindrical portion 93B is supported on and secured to the block portion 93A. The diameter D1 of the cylindrical portion 93B may be, but not limited to, 42 mm, for example.

The detection target 93 (the block portion 93A and the cylindrical portion 93B) is made of a light-transmitting material. Thus, the light from the light emitter 51 passes through the detection target 93 (the block portion 93A and the cylindrical portion 93B). The material of the detection target 93 (the block portion 93A and the cylindrical portion 93B) may be, but not limited to, colorless transparent glass or colored transparent glass, for example. In the present embodiment, the detection target 93 (the block portion 93A and the cylindrical portion 93B) is made of colorless transparent glass.

When the optical axis of the object detection sensor 5 is perpendicular to a surface of the block portion 93A, the light from the light emitter 51 travels straight without refraction at that surface (hereinafter, incident surface) of the block portion 93A. In this case, the light from the light emitter 51 is received by the light receiver 52, and thus the detection state by the object detection sensor 5 is ON. When the optical axis of the object detection sensor 5 is not perpendicular to the incident surface of the block portion 93A and is inclined with respect to the normal to the incident surface, the light from the light emitter 51 is refracted at the incident surface and travels through the block portion 93A. While the angle of inclination of the optical axis with respect to the normal to the incident surface is relatively small, the light emitted from the light emitter 51 is received by the light receiver 52 although the amount of received light (light intensity) is reduced. Thus, the detection state by the object detection sensor 5 is ON. Once the inclination angle of the optical axis with respect to the normal to the incident surface exceeds a certain value, the light from the light emitter 51 is no longer received by the light receiver 52. Thus, the detection state by the object detection sensor 5 changes to OFF. That is, when the optical axis of the object detection sensor 5 is perpendicular to the incident surface of the block portion 93A, the detection state by the object detection sensor 5 is ON, and the amount of light (intensity of light) received by the light receiver 52 is at its maximum.

When the optical axis of the object detection sensor 5 is perpendicular to a tangent plane to the lateral surface 938 of the cylindrical portion 93B, the light from the light emitter 51 travels straight without refraction at the lateral surface 938 and passes through the center line CL of the cylindrical portion 93B. In this case, the light from the light emitter 51 is received by the light receiver 52, and thus the detection state by the object detection sensor 5 is ON. When the optical axis of the object detection sensor 5 is not perpendicular to a tangent plane to the lateral surface 938 of the cylindrical portion 93B and is inclined with respect to the normal to the tangent plane, the light from the light emitter 51 is refracted at the lateral surface 938 of the cylindrical portion 93B, travels through the cylindrical portion 93B, and is refracted again at the lateral surface 938 before exiting. In this case, the light from the light emitter 51 is no longer received by the light receiver 52, and thus the detection state by the object detection sensor 5 changes to OFF.

Next, the following describes a teaching process for enabling automatic teaching work, according to the present embodiment.

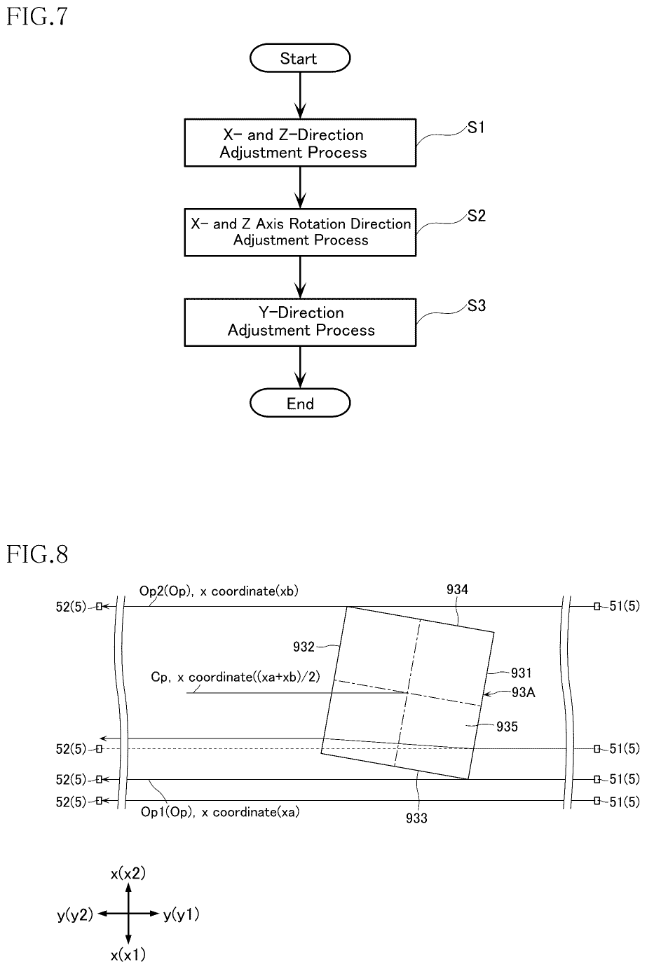

FIG. 7 is a flowchart of a teaching process performed by the control device 6. The control device 6 (the control unit 61) starts the teaching process in response to, for example, an instruction entered into the input unit 72 by an operator. The teaching work involves adjusting the positions in the x, y, and z directions and the angles around the rotational directions around x and z directions. The teaching process includes an x- and z-direction adjustment process (S1), an x- and z-axis rotation direction adjustment process (S2), and a y-direction adjustment process (S3).

### <X- and Z-Direction Adjustment Process>

FIG. 8 is a view illustrating an example of an x-direction adjustment process. The x-direction adjustment process is performed by using the block portion 93A of the detection target 93. FIG. 8 shows only the block portion 93A of the detection target 93, omitting the cylindrical portion 93B. FIG. 8 schematically shows the positions of the optical axis Op of the object detection sensor 5 disposed on the hand 4 relative to the block portion 93A, as seen in the z direction from the z1 side toward the z2 side. The optical axis Op of the object detection sensor 5 is a straight line connecting the light emitter 51 and the light receiver 52 at their centers. In the illustrated example, with respect to the hand 4, the block portion 93A is tilted clockwise in the direction of rotation around the z-axis. The deviation angle of the block portion 93A with respect to the hand 4 in the direction of rotation around the z-axis is about 2 degrees or less, for example. In FIG. 8, the deviation angle of the block portion 93A is shown exaggerated for clarity. Note that the angle is expressed in degrees, and this also applies to the following description.

In the x-direction adjustment process, while the detection by the object detection sensor 5 is performed, the hand 4 is moved in the x direction toward the x2 side. In this adjustment process, the height (the position in the z direction) of the hand 4 is set such that the block portion 93A is detectable by moving the hand 4 in the x direction. In this example, the hand 4 is placed such that the optical axis Op of the object detection sensor 5 passes the x1 side in the x direction with respect to the block portion 93A. In this state, block portion 93A (the detection target 93) is not located between the light emitter 51 and the light receiver 52. Thus, the detection state by the object detection sensor 5 is ON. Then, as the hand 4 is moved in the x direction toward the x2 side, there is a point at which the optical axis Op of the object detection sensor 5 is blocked by an edge of the block portion 93A. In the illustrated example, the optical axis Op of the object detection sensor 5 is blocked by the edge between the first surface 931 and the third surface 933. The optical axis Op at the point when it reaches the edge is defined as the optical axis Op1.

As the hand 4 is moved further in the x direction toward the x2 side, the light from the light emitter 51 passes through the first surface 931, the inside of the block portion 93A, and the second surface 932. In this state, the light from the light emitter 51 is refracted at the first surface 931 and the second surface 932 and is no longer received by the light receiver 52. Thus, the detection state by the object detection sensor 5 changes to OFF. As the hand 4 is moved further in the x direction toward the x2 side, the light from the light emitter 51 is reflected off the fourth surface 934 and is not received by the light receiver 52. Thus, the detection state by the object detection sensor 5 remains OFF. As the hand 4 is moved further in the x direction toward the x2 side, there is a point at which the optical axis Op of the object detection sensor 5 reaches the edge between the fourth surface 934 and the second surface 932. The optical axis Op at the point when it reaches the edge is defined as the optical axis Op2. As the hand 4 is moved further in the x direction toward the x2 side, the optical axis Op passes a position away from the edge between the fourth surface 934 and the second surface 932 in the direction toward the x2 side. In this state, block portion 93A (the detection target 93) is no longer located between the light emitter 51 and the light receiver 52. Thus, the detection state by the object detection sensor 5 changes to ON.

Based on the change of the detection state by the object detection sensor 5, the positions (x coordinates) of the optical axes Op1 and Op2 are recorded in the storage unit 62. The x coordinate of the center Cp of the block portion 93A is given by (xa+xb)/2, where xa is the x coordinate of the optical axis Op1, and xb is the x coordinate of the optical axis Op2. Once the x coordinate of the center Cp of the block portion 93A is calculated, the position of the hand 4 in the x direction is adjusted based on the thus calculated x coordinate of the center Cp. In this example, the position of the hand 4 in the x direction is adjusted to align the optical axis Op of the object detection sensor 5 with the center Cp of the block portion 93A as viewed in the z direction.

In the example shown in FIG. 8, the detection state by the object detection sensor 5 sequentially changes ON→OFF→ON as the hand 4 is moved in the x direction toward the x2 side. The detection state by the object detection sensor 5 is OFF only during the time the optical axis Op intersects the block portion 93A. Consider the case where the deviation angle of the block portion 93A with respect to the hand 4 in the direction of rotation around the z-axis is smaller than that in the example shown in FIG. 8. In this case, the light from the light emitter 51 may be received by the light receiver 52 although it is refracted by the block portion 93A. Yet, the amount of light (intensity of light) received by the light receiver 52 changes (e.g., decreases) when the optical axis Op of the object detection sensor 5 intersects the block portion 93A. Thus, based on the changes in the amount of light (intensity of light) received by the light receiver 52, the positions (x coordinates) of the optical axes Op1 and Op2 are recorded in the storage unit 62 as in the example of FIG. 8. Then, the x coordinate of the center Cp of the block portion 93A is calculated from the x coordinates of the optical axes Op1 and Op2.

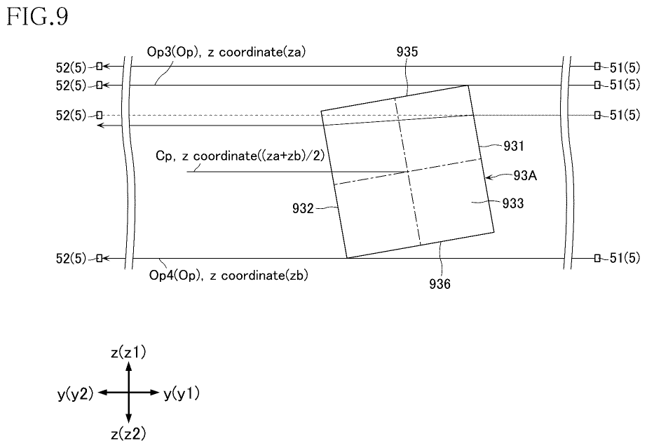

FIG. 9 illustrates an example of a z-direction adjustment process. The z-direction adjustment process is performed using the block portion 93A of the detection target 93. FIG. 9 shows only the block portion 93A of the detection target 93, omitting the cylindrical portion 93B. Specifically, FIG. 9 schematically shows the positions of the optical axis Op of the object detection sensor 5 disposed on the hand 4 relative to the block portion 93A, as seen in the x direction from the x1 side toward the x2 side. In the illustrated example, the block portion 93A is tilted counterclockwise in the direction of rotation around the x-axis with respect to the hand 4. The deviation angle of the block portion 93A with respect to the hand 4 in the direction of rotation around the x-axis is about 2 degrees or less, for example. In FIG. 9, the deviation angle of the block portion 93A is shown exaggerated for clarity.

In the z-direction adjustment process, while the object detection sensor 5 is performing the detection, the hand 4 is moved in the z direction toward the z2 side. In this adjustment process, the position of the hand 4 in the x direction is set such that the block portion 93A is detectable by moving the hand 4 in the z direction. In this example, the hand 4 is placed such that the optical axis Op of the object detection sensor 5 passes the z1 side in the z direction with respect to the block portion 93A. In this state, the block portion 93A is not located between the light emitter 51 and the light receiver 52. Thus, the detection state by the object detection sensor 5 is ON. Then, as the hand 4 is moved in the z direction toward the z2 side, there is a point at which the optical axis Op of the object detection sensor 5 is blocked by an edge of the block portion 93A. In the illustrated example, the optical axis Op of the object detection sensor 5 is blocked by the edge between the first surface 931 and the fifth surface 935. The optical axis Op at the point when it reaches the edge is defined as the optical axis Op3.

As the hand 4 is moved further in the z direction toward the z2 side, the light from the light emitter 51 passes through the first surface 931, the inside of the block portion 93A, and the second surface 932. In this state, the light from the light emitter 51 is refracted at the first surface 931 and the second surface 932 and is no longer received by the light receiver 52. Thus, the detection state by the object detection sensor 5 changes to OFF. As the hand 4 is moved further in the z direction toward the z2 side, the light from the light emitter 51 is reflected off the sixth surface 936 and is not received by the light receiver 52. Thus, the detection state by the object detection sensor 5 remains OFF. As the hand 4 is moved further in the z direction toward the z2 side, there is a point at which the optical axis Op of the object detection sensor 5 reaches the edge between the sixth surface 936 and the second surface 932. The optical axis Op at the point when it reaches the edge is defined as the optical axis Op4. As the hand 4 is moved further in the z direction toward the z2 side, the optical axis Op passes a position away from the edge between the sixth surface 936 and the second surface 932 in the z direction toward the z2 side. In this state, block portion 93A (the detection target 93) is no longer located between the light emitter 51 and the light receiver 52. Thus, the detection state by the object detection sensor 5 changes to ON.

Based on the change of the detection state by the object detection sensor 5, the positions (z coordinates) of the optical axes Op3 and Op4 are recorded in the storage unit 62. The z coordinate of the center Cp of the block portion 93A is given by (za+zb)/2, where za is the z coordinate of the optical axis Op3, and zb is the z coordinate of the optical axis Op4. Once the z coordinate of the center Cp of the block portion 93A is calculated, the position of the hand 4 in the z direction is adjusted based on the thus calculated z coordinate of the center Cp. In this example, the position of the hand 4 in the z direction is adjusted to align the optical axis Op of the object detection sensor 5 with the center Cp of the block portion 93A as viewed in the x direction.

In the example shown in FIG. 9, the detection state by the object detection sensor 5 sequentially changes ON→OFF→ON as the hand 4 is moved in the z direction toward the z2 side. The detection state by the object detection sensor 5 is OFF only during the time the optical axis Op intersects the block portion 93A. Consider the case where the deviation angle of the block portion 93A with respect to the hand 4 in the direction of rotation around the x-axis is smaller than that in the example shown in FIG. 9. In this case, the light from the light emitter 51 may be received by the light receiver 52 although it is refracted by the block portion 93A. Yet, the amount of light (intensity of light) received by the light receiver 52 changes (e.g., decreases) when the optical axis Op of the object detection sensor 5 intersects the block portion 93A. Thus, based on the changes in the amount of light (intensity of light) received by the light receiver 52, the positions (z coordinates) of the optical axes Op3 and Op4 are recorded in the storage unit 62 as in the example of FIG. 9. Then, the z coordinate of the center Cp of the block portion 93A is calculated from the z coordinates of the optical axes Op3 and Op4.

Consider the case where the deviation angle of the block portion 93A with respect to the hand 4 in the direction of rotation around the x-axis is extremely small. In this case, the light from the light emitter 51 undergoes almost no refraction and travels straight through the block portion 93A to reach the light receiver 52. Then, it is difficult to distinguish this case from the case where block portion 93A (the detection target 93) is not located between the light emitter 51 and the light receiver 52. In view of this, it is desirable that the block portion 93A is made of a material that absorbs the wavelengths of light emitted from the light emitter 51. Examples of such a material include colored transparent glass. The block portion 93A that is made of colored transparent glass attenuates the light as it passes through the block portion 93A, clearly distinguishing it from the case where the block portion 93A is not located between the light emitter 51 and the light receiver 52.

### <X- and Z-Axis Rotation Direction Adjustment Process>

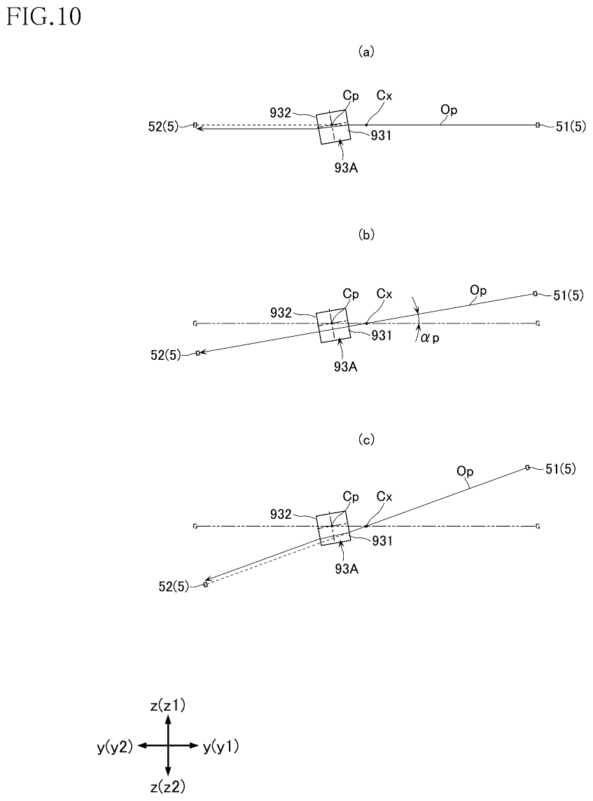

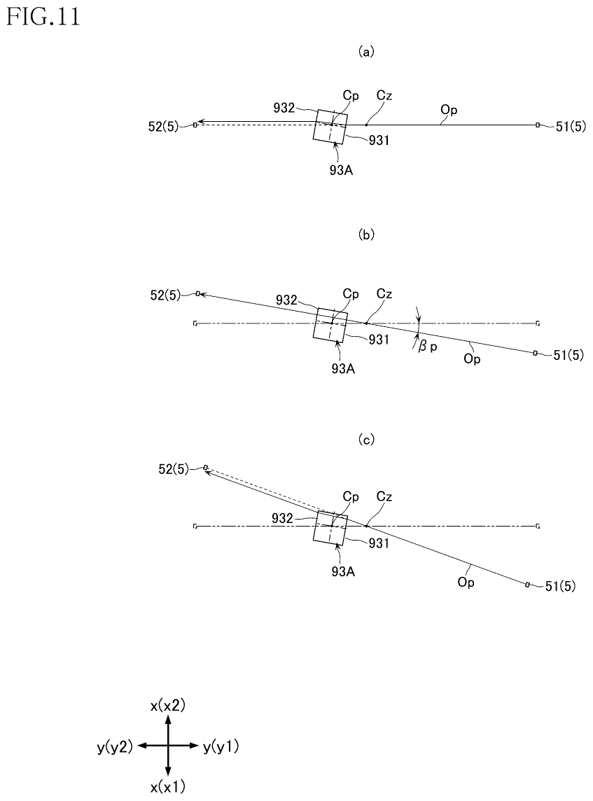

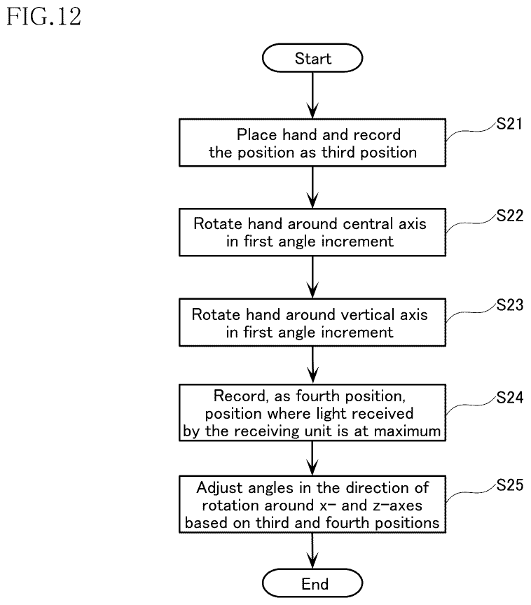

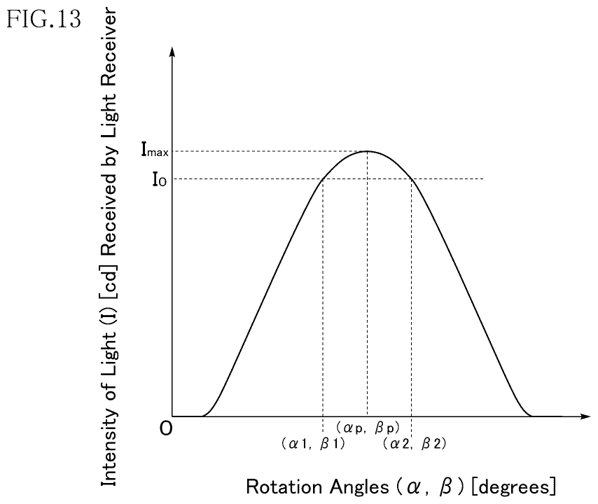

FIGS. 10 and 11 are views illustrating an example of an x- and z-axis rotation direction adjustment process. The x- and z-axis rotation direction adjustment process is performed by using the block portion 93A of the detection target 93. FIGS. 10 and 11 show only the block portion 93A of the detection target 93, omitting the cylindrical portion 93B. FIG. 10 schematically shows the positions of the object detection sensor 5 disposed on the hand 4 relative to the block portion 93A, as seen in the x direction from the x1 side toward the x2 side. FIG. 11 schematically shows the positions of the object detection sensor 5 disposed on the hand 4 relative to the block portion 93A, as seen in the z direction from the z1 side toward the z2 side. FIG. 12 is a flowchart of an example of an x- and z-axis rotation direction adjustment process.

In the x- and z-axis rotation direction adjustment process, first, the position of the hand 4 is adjusted in the z direction such that the optical axis Op of the object detection sensor 5 is aligned with the center Cp of the block portion 93A as viewed in the x direction (see FIG. 10(a)). Additionally, the position of the hand 4 is adjusted in the x direction such that the optical axis Op of the object detection sensor 5 is aligned with the center Cp of the block portion 93A as viewed in the z direction (see FIG. 11(a)). In this state, the light from the light emitter 51 passes through the first surface 931, the inside of the block portion 93A, and the second surface 932 (the third state). This position of the hand 4 is recorded as a third position into the storage unit 62 (Step S21 in FIG. 12). In this example, the block portion 93A is tilted counterclockwise in the direction of rotation around the x-axis with respect to the hand 4 as shown in FIG. 10. The block portion 93A is also tilted clockwise in the direction of rotation around the z-axis with respect to the hand 4 as shown in FIG. 11. When the hand 4 is at the third position, the light from the light emitter 51 is refracted at the first surface 931 and the second surface 932 and is not received by the light receiver 52. Thus, the detection state by the object detection sensor 5 is OFF.

Subsequently, while the object detection sensor 5 is performing the detection, the hand 4 is rotated around the central axis Cx (see FIGS. 10(b) and (c)). The central axis Cx extends in the x direction and intersects the optical axis Op of the object detection sensor 5 at the midpoint of the optical axis Op. Rotation of the hand 4 around the central axis Cx is made by the vertical arm assembly 1 and the first rotation member 2 that are appropriately driven by the drive mechanism 71. Subsequently, while the object detection sensor 5 is performing the detection, the hand 4 is rotated around the vertical axis Cz (see FIGS. 11(b) and (c)). The vertical axis Cz extends in the z direction and intersects the optical axis Op of the object detection sensor 5 at the midpoint of the optical axis Op. Rotation of the hand 4 around the vertical axis Cz is made by the vertical arm assembly 1, the first rotation member 2, and the horizontal arm assembly 3 that are appropriately driven by the drive mechanism 71.

In the present embodiment, the hand 4 is rotated from the third position around the central axis Cx within a range of a predetermined first scanning angle, in increments of a predetermined first angle α0 (Step S22 in FIG. 12). For each increment of the first angle α0, in addition, the hand 4 is rotated around the vertical axis Cz within a range of a second scanning angle (Step S23 in FIG. 12).

The first scanning angle within which the hand 4 is rotated around the central axis Cx is not limited to a specific angle. In the present embodiment, as mentioned earlier, the deviation angle of the block portion 93A with respect to the hand 4 in the direction of rotation around the x-axis is about 2 degrees or less. In this case, the first scanning angle is between 5 degrees and 8 degrees or so, for example. The second scanning angle within which the hand 4 is rotated around the vertical axis Cz is not limited to a specific angle. In the present embodiment, as mentioned earlier, the deviation angle of the block portion 93A with respect to the hand 4 in the direction of rotation around the z-axis is about 2 degrees or less. In this case, the second scanning angle is between 5 degrees and 8 degrees or so, for example. The first angle α0 for the stepwise rotation of the hand 4 around the central axis Cx is not limited to a specific angle. The smaller first angle α0 increases the accuracy in detecting the amount of light received by the object detection sensor 5 (the light receiver 52). In one example, the first angle α0 may be 0.1 degrees.

In FIG. 10(b) and FIG. 11(b), the optical axis Op of the object detection sensor 5 is perpendicular to the first surface 931. In this state, light from the light emitter 51 travels straight without refraction neither at the first surface 931 nor at the second surface 932 of the block portion 93A, reaching the light receiver 52 along the optical axis Op. The hand 4 shown in FIG. 10(b) and FIG. 11(b) are in the state in which the amount of light (intensity of light) received by the light receiver 52 is at its maximum (fourth state). This position of the hand 4 is recorded as a fourth position into the storage unit 62 (Step S24 in FIG. 12).

Then, based on the third position of the hand 4 in the third state shown in FIG. 10(a) and FIG. 11(a) and the fourth position of the hand 4 in the fourth state shown in FIG. 10(b) and FIG. 11(b), the rotation angle αp around the central axis Cx (see FIG. 10(b)) and the rotation angle βp around the vertical axis Cz (see FIG. 11(b)) through which the hand 4 has been rotated from the third state to the fourth state are calculated. Then, based on the rotation angles αp and βp, the hand 4 is adjusted with respect to the angle in the direction of rotation around the x axis (around the central axis Cx) and the angle in the direction of rotation around the z axis (around the vertical axis Cz) (Step S25 in FIG. 12).

FIG. 13 is a view for illustrating a method for determining the angles of rotation around the x- and z-axes at which the amount of light received by the light receiver 52 is at its maximum. A first determination method begins with determining the maximum amount (intensity) of light (Imax) received by the light receiver 52 while the hand 4 is rotated around the central axis Cx to the rotation angle α within the first scanning angle and around the vertical axis Cz to the rotation angle β within the range of the second scanning angle. Then, the rotation angles αp and βp of the hand 4 at which the maximum amount of light is received are calculated. A second method being with determining a pair of angles α1 and β1 and a pair of angles α2 and β2 at which the amount of light received by the light receiver 52 reaches (exceeds and falls short of) the light intensity threshold I₀ while the hand 4 is rotated to the rotation angle α within the first scanning angle and to the rotation angle β within the range of the second scanning angle. Then, the midpoints between the pairs of angles are calculated as the rotation angles αp and βp.

### <Y-Direction Adjustment>

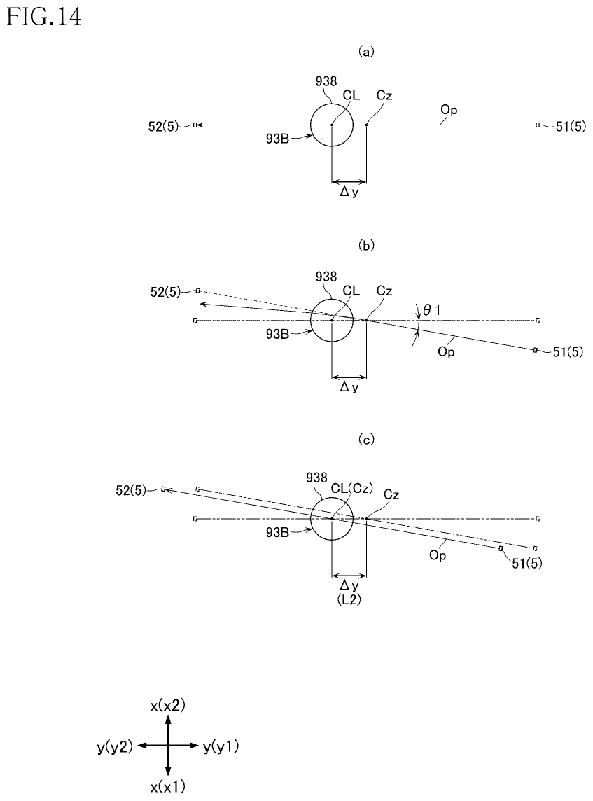

FIG. 14 illustrates an example of a y-direction adjustment process. The y-direction adjustment process is performed using the cylindrical portion 93B of the detection target 93. FIG. 14 shows only the cylindrical portion 93B of the detection target 93, omitting the block portion 93A. FIG. 14 schematically shows the positions of the optical axis Op of the object detection sensor 5 disposed on the hand 4 relative to the cylindrical portion 93B, as seen in the z direction from the z1 side toward the z2 side. Although not shown in the figures, the center line CL of the cylindrical portion 93B is aligned with the center Cp of the block portion 93A as seen in the z direction.

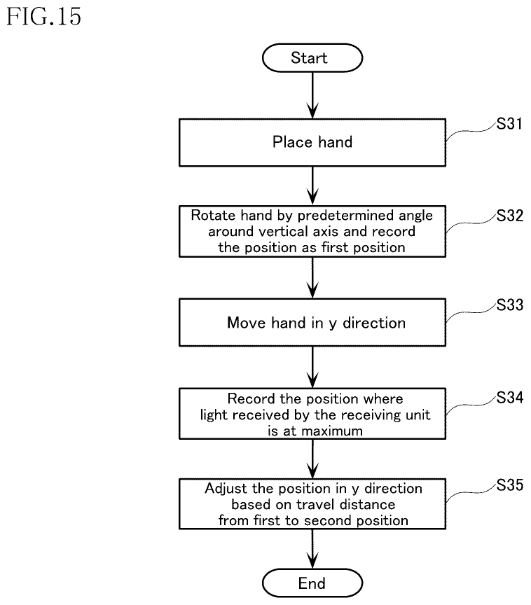

Although not illustrated, the y-direction adjustment process begins with adjusting the position of the hand 4 in the z direction and the angle of the hand 4 in the direction of rotation around the x-axis such that the optical axis Op of the object detection sensor 5 is aligned with the center Cp of the block portion 93A and that the optical axis Op is perpendicular to the first surface 931 as viewed in the x direction. Additionally, the position of the hand 4 in the x direction and the angle of the hand 4 in the direction of rotation around the z-axis are also adjusted such that the optical axis Op of the object detection sensor 5 is aligned with the center Cp of the block portion 93A and that the optical axis Op is perpendicular to the first surface 931 as viewed in the z direction. These adjustments may be made through the x- and z-direction adjustment process (S1) and the x- and z-axis rotation direction adjustment process (S2) described above. In this state, the hand 4 has been adjusted except for the deviation in the y direction with respect to the block portion 93A (the detection target 93) (FIG. 14(a)). In the y-direction adjustment process, the height (the position in the z direction) of the hand 4 is set such that the cylindrical portion 93B is detectable by moving the hand 4 along the horizontal plane (the xy plane) (Step S31 in FIG. 15). As shown in FIG. 14(a), as viewed in the z direction, the distance in the y direction between the vertical axis Cz, which is the rotation center of the hand 4, and the center line CL of the cylindrical portion 93B corresponds to the amount of deviation (Δy) of the hand 4 in the y direction from the cylindrical portion 93B (the detection target 93). In the present embodiment, as viewed in the z direction, the hand 4 (the vertical axis Cz) deviates in the y direction from the detection target 93 (the center line CL) toward the y1 side. In one example, the amount of deviation Δy of the hand 4 in the y direction from the cylindrical portion 93B is about 5 mm or less. In FIG. 14, the amount of deviation Δy of the hand 4 in the y direction from the cylindrical portion 93B is shown exaggerated for clarity.

When the hand 4 is placed at the position shown in FIG. 14(a), the optical axis Op of the object detection sensor 5 is perpendicular to a tangent plane to the lateral surface 938 of the cylindrical portion 93B (more precisely, the tangent plane at the point where the optical axis Op meets the lateral surface 938). In this state, the light from the light emitter 51 of the object detection sensor 5 travels straight without refraction at the lateral surface 938 of the cylindrical portion 93B and passes through the center line CL of the cylindrical portion 93B. Thus, the light from the light emitter 51 is received by the light receiver 52, and the detection state by the object detection sensor 5 is ON.

Subsequently, the hand 4 is rotated by a predetermined angle around the vertical axis Cz (see FIG. 14(b)). In the illustrated example, the hand 4 is rotated (clockwise) by a predetermined angle θ1 around the vertical axis Cz as viewed in the z direction. In this state, the optical axis Op of the object detection sensor 5 is not perpendicular to a tangent plane to the lateral surface 938 of the cylindrical portion 93B. Rather, the optical axis Op is inclined with respect to the normal to the tangent plane. Thus, the light from the light emitter 51 is refracted at the lateral surface 938 of the cylindrical portion 93B, travels through the cylindrical portion 93B, and is refracted again at the lateral surface 938 before exiting. Eventually, the light from the light emitter 51 is no longer received by the light receiver 52, and the detection state by the object detection sensor 5 changes to OFF (first state). This position of the hand 4 is recorded as a first position into the storage unit 62 (Step S32 in FIG. 15).

Subsequently, while the object detection sensor 5 is performing the detection, the hand 4 is moved in the y direction toward the y2 side (Step S33 in FIG. 15). When the optical axis Op of the object detection sensor 5 is perpendicular to a tangent plane to the lateral surface 938 as viewed in the z direction as shown in FIG. 14(c), the light from the light emitter 51 travels straight without refraction at the lateral surface 938 of the cylindrical portion 93B and passes through the center line CL of the cylindrical portion 93B. Thus, the light from the light emitter 51 is received by the light receiver 52. As a result, the detection state by the object detection sensor 5 is ON, and the amount of light received by the light receiver 52 is at its maximum (second state). This position of the hand 4 is recorded as a second position into the storage unit 62 (Step S34 in FIG. 15).

Then, the position of the hand 4 in the y direction is adjusted based on a travel distance L2 that is the distance traveled by the hand 4 from the first position at which the hand 4 is in the first state as shown in FIG. 14(b) to the second position at which the hand 4 is in the second state as shown in FIG. 14(C) (Step S35 in FIG. 15). The travel distance L2 corresponds to the amount of deviation (Δy) of the hand 4 in the y direction from the cylindrical portion 93B when the hand 4 is brought from the first state into the second state.

The following describes operations of the present embodiment.

According to the present embodiment, teaching work is automatically performed through the teaching process performed by the control device 6. The teaching process requires very few and simple manual operations by a human operator. Thus, the time required for teaching work is substantially reduced. In addition, the teaching process is performed using an object detection sensor attached to the hand of a common transfer robot, not requiring an additional component provided to the transfer robot.

The transfer robot A1 includes the vertical arm assembly 1, the first rotation member 2, and the horizontal arm assembly 3. The hand 4 is supported by the horizontal arm assembly 3, and the object detection sensor 5 is attached to the hand 4. The object detection sensor 5 detects the detection target 93 while the hand 4 is moved. Based on the detection results, the positions of the hand 4 are used for teaching by the control device 6. The detection target 93 includes the cylindrical portion 93B that is made of a light-transmitting material and has the shape of a cylindrical column. The cylindrical portion 93B has the center line CL extending in the z direction (the vertical direction). The object detection sensor 5 includes the light emitter 51 and the light receiver 52 for receiving the light from the light emitter 51. The control device 6 rotates the hand 4 by a predetermined angle around the vertical axis Cz that intersects the optical axis Op of the object detection sensor 5 at the midpoint of the optical axis Op to bring the hand 4 into the first state in which light from the light emitter passes through the cylindrical portion 93B. Subsequently, the control device 6 moves the hand 4 in the y direction to bring the hand 4 into the second state in which the amount of light received by the light receiver 52 is at its maximum. The control device 6 then adjusts the position of the hand 4 in the y direction based on the travel distance L2 of the hand 4 from the first state to the second state. This configuration enables adjusting the position of the hand 4 by first rotating the hand 4 around the vertical axis Cz that extends in the z direction and then moving the hand 4 in the y direction while detection of the detection target 93 is being performed. In this way, the position of the hand 4 in the y direction is efficiently adjusted without complex multistep processes.

The detection target 93 includes the block portion 93A that is made of a light-transmitting material. The block portion 93A has the first surface 931 and the second surface 932 respectively facing toward the y1 side and the y2 side in the y direction. This configuration ensures that the angles of the hand 4 in the direction of rotation around the x- and z axes are efficiently adjusted based on the results of the detection of the detection target 93 performed while the hand 4 is rotated around the central axis Cx extending in the x direction and the vertical axis Cz extending in the z direction.

The cylindrical portion 93B is located on the z1 side in the z direction (the upper side in the vertical direction) with respect to the block portion 93A. This configuration allows the detection target 93 composed of the block portion 93A and the cylindrical portion 93B to be efficiently fit into a small space.

In the present embodiment, the detection target 93 (the block portion 93A and the cylindrical portion 93B) is made of colorless or colored transparent glass.

With this configuration, the diffusion of light passing through the detection target 93 (the block portion 93A and the cylindrical portion 93B) is reduced and thus the accuracy of the detection by the object detection sensor 5 (the light receiver 52) is increased.

The transfer robot teaching system and the transfer robot teaching method according to the present disclosure are not limited to the embodiment described above. Various modifications in design may be made freely in the specific structure of the transfer robot teaching system and the transfer robot teaching method according to the present disclosure. For example, while the detection target 93 is disposed on the cassette 8 in the embodiment described above, the detection target 93 may be disposed on a load lock chamber and used for teaching work.

### REFERENCE NUMERALS

| | | |
|---|---|---|
| A1: transfer robot | 1: vertical arm | 2: first rotation member |
| | assembly | |
| 3: horizontal arm | 4, 4A, 4B: hand | 5: object detection |
| assembly | | sensor |
| 51: light emitter | 52: light receiver | 6: control device |
| 93: detection target | 93A: block portion | 93B: cylindrical portion |
| 931: first surface | 932: second surface | 933: third surface |
| 934: fourth surface | 935: fifth surface | 936: sixth surface |
| L2: travel distance | Ox: first rotation axis | CL: center line |
| Cx: central axis | Cz: vertical axis | |

1. A teaching system for a transfer robot, the robot provided with:
a vertical arm assembly of a vertical articulated type configured to move in an in-plane direction perpendicular to a horizontal first direction;
a first rotation member supported by the vertical arm assembly to be rotatable around a first rotation axis extending in the first direction;
a horizontal arm assembly of a horizontal articulated type supported by the first rotation member;
a hand supported by the horizontal arm assembly and provided with an object detection sensor; and
a control device that detects a detection target with the object detection sensor while moving the hand and teaches a position of the hand using a detection result,
wherein the detection target includes a cylindrical portion made of a light-transmitting material and having a center line extending in a vertical direction perpendicular to the first direction,
the object detection sensor includes a light emitter and a light receiver for receiving light from the light emitter, and
the control device is configured to:
rotate the hand by a predetermined angle around a vertical axis located at a midpoint of an optical axis of the object detection sensor and extending in the vertical direction;
move the hand in a second direction perpendicular to the first direction and the vertical direction from a first state in which light form the light emitter passes through the cylindrical portion to a second state in which the light receiver receives a maximum amount of light; and
adjust a position of the hand in the second direction based on a travel distance of the hand from the first state to the second state.

2. The teaching system according to claim 1, wherein the detection target includes a block portion that is made of a light-transmitting material, and
the block portion includes a first surface facing toward a first side in the second direction and a second surface facing toward a second side in the second direction and parallel to the first surface.

3. The teaching system according to claim 2, wherein the cylindrical portion is located on an upper side in the vertical direction with respect to the block portion.

4. The teaching system according to claim 1, wherein the detection target is made of colorless transparent glass or colored transparent glass.

5. A teaching method for a transfer robot, the robot provided with:
a vertical arm assembly of a vertical articulated type configured to move in an in-plane direction perpendicular to a first direction that is horizontal;
a first rotation member supported by the vertical arm assembly to be rotatable around a first rotation axis that extends in the first direction;
a horizontal arm assembly of a horizontal articulated type supported by the first rotation member; and
a hand supported by the horizontal arm assembly and provided with an object detection sensor, wherein the teaching method is configured to detect a detection target with the object detection sensor while moving the hand and teach a position of the hand using a detection result,
wherein the detection target includes a cylindrical portion made of a light-transmitting material and having a center line extending in a vertical direction perpendicular to the first direction, and
the object detection sensor includes a light emitter and a light receiver for receiving light from the light emitter,
the method comprising:
rotating the hand by a predetermined angle around a vertical axis located at a midpoint of an optical axis of the object detection sensor and extending in the vertical direction to bring the hand into a first state in which light form the light emitter passes through the cylindrical portion;
recording a position of the hand in the first state as a first position;
moving the hand in a second direction to bring the hand into a second state in which the light receiver receives a maximum amount of light and recording a position of the hand that is in the second state as a second position; and
adjusting a position of the hand in the second direction based on a travel distance of the hand from the first position to the second position.
